(19) United States
(12) Patent Application Publication
(10) Pub. No.: US 2026/0050705 A1
(43) Pub. Date: Feb. 19, 2026

(54) METHOD AND SYSTEM FOR GENERATING A NEW TECHNICAL SOLUTION

(71) Applicant: Airbus SAS, BLAGNAC (FR)

(72) Inventor: Francois Gabriel Yves ROUYRE, BLAGNAC (FR)

(21) Appl. No.: 19/301,018

(22) Filed: Aug. 15, 2025

(30) Foreign Application Priority Data
Aug. 16, 2024 (FR) FR2408942

(51) Int. Cl. G06F 30/17

(52) U.S. Cl. CPC G06F 30/17

(57) ABSTRACT

A method and system for generating a new technical solution by acquiring PLM data of an industrial product having at least two 3D objects, extracting attributes and rules for each 3D object from the PLM data, generating a knowledge graph of tree relationships between the 3D objects, generating topology attributes for each 3D object, consolidating, for each 3D object, its attributes and rules, its tree relationships and its topology attributes into at least one relational database, in voxel form, receiving a request from a user relating to a technical solution, the request having at least one 3D volume, evaluating whether the technical solution is present in the PLM, and when it is not present: generating a new technical solution in the 3D volume, implementing at least one new 3D object, generating a new voxel associated with the new 3D object, and re-introducing the new voxel into the relational database.

### CROSS-REFERENCES TO RELATED APPLICATIONS

This application claims the benefit of French Patent Application Number FR2408942 filed on Aug. 16, 2024, the entire disclosure of which is incorporated herein by way of reference.

### FIELD OF THE INVENTION

The present invention relates to a method and a system for generating a new technical solution, and more specifically to a method and a system for proposing a technical solution implementing a new 3D object generated from PLM data of existing elementary parts, consolidated into voxel form.

### BACKGROUND OF THE INVENTION

The management of the life cycle of an industrial product, such as an aircraft, a motor vehicle, a train, etc., also called PLM (Product Lifecycle Management), is an internal process within a company that manages the entire life cycle of an industrial product from its conceptualization, its development and its commissioning up to its disposal. It involves managing everything related to the product, from the beginning until the end of its life cycle.

Within this context, a 3D digital mock-up (DMU) is also an essential tool for handling competitiveness, industrial product quality and safety. Its effectiveness has been proven in supporting the definition, the manufacture, the maintenance and the use of said industrial products. It is generally generated by Computer Aided Design (CAD) software. It is useful to all departments within a company involved in the design, the manufacture, the maintenance and the use of industrial products, but generally cannot be used as is, as not all the departments are necessarily equipped with the same tools and/or the same computing power as the department that produced a given 3D digital mock-up. Typically, they do not all use the same CAD software.

Each department generates and handles a large amount of data, and in most cases this data is siloed, is in a format and is optimized for processing performance that is not standardized across departments. Thus, using data produced by other departments, when necessary, requires adaptation and manual intervention, and there is no cross-functional service or “streamlined and/or simplified” (i.e., less computer resource-intensive) version of the 3D digital mock-up to facilitate user activities in the operations related to the industrial product, and notably related to retrieving the 3D definition file for the customized needs of these other departments.

Furthermore, it is difficult to identify the function of a 3D object that forms part of the composition of an industrial product solely based on the shapes or dimensions of the object, insofar as its identification in the various 3D digital mock-ups involves technical parameters or features that are not the same from one 3D digital mock-up to another. The above comments fully or partly apply to the case of elementary parts that are not 3D objects derived from digital mock-ups, but are standard parts available on the market that also form part of the PLM, with corresponding PLM data.

New developments are therefore needed in order to link all the existing databases within the company, including the representation of 3D objects, in a vast network made up of interdependencies, information and features concerning each elementary part that makes up an industrial product, that is managed or has to be managed in any department of the company, throughout the entire life cycle (definition, manufacturing, maintenance, operation, disposal, recycling) of the industrial product. These developments must be implemented in order to manage any computer environment, using 3D CAD objects and metadata in databases in order to link them in an organized and smart network capable of transitioning from one 3D environment to another, but also, without compromising the existing management of the life cycle of the industrial product, in order to allow all the information relating to an elementary part to be retrieved, and even allowing new technical design solutions to be designed for portions of the industrial product.

The techniques mentioned in this section should not be presumed to belong to the prior art simply because they are mentioned. Similarly, a problem mentioned in this section should not be presumed to have been previously identified in the prior art simply because it is mentioned.

### SUMMARY OF THE INVENTION

Embodiments of the present invention have been developed based on the understanding of the developers concerning the shortcomings associated with the prior art. The invention generally proposes a method and a system for using the one or more 3D digital mock-ups of any type (tooling, factories, in operation, etc.) of an industrial product, at any granularity level in the PBS (Product Breakdown Structure) tree breakdown of the elementary parts forming the industrial product, and in contexts:
meeting the “digital twin” concept (i.e., an exact digital replica of the industrial product, continuously updated throughout the life cycle of the industrial product, and acting as a digital counterpart that is effectively indistinguishable for practical purposes, such as simulation, integration, testing, monitoring and maintenance);
streamlined 3D distribution (democratization of 3D access without a computer/CAD software); and
industrial product management activities through the 3D digital mock-up, which geometrically positions each elementary part in relation to the other elementary parts forming the industrial product (ease of computation, layout, organization, understanding, model generation).

More specifically, the present invention comprises, in various embodiments, a method for generating a new technical solution, comprising the steps of:
acquiring PLM data of an industrial product comprising at least two elementary parts, at least one of which is a 3D object generated by a 3D digital model;
extracting attributes and rules for each elementary part from the PLM data;
generating a knowledge graph of tree relationships establishing logical relationships between the elementary parts on the geometric and functional levels;
generating topology attributes for each elementary part;
consolidating, for each elementary part, the attributes and rules, the tree relationships and the topology attributes into at least one relational database, in voxel form;
receiving a request from a user relating to a technical solution, the request comprising at least one 3D volume;
evaluating whether the technical solution is present in the PLM, and if it is not present:
generating and providing, in response to the request from the user, a new technical solution in the 3D volume, implementing at least one new 3D object;
generating a new voxel associated with the new 3D object; and
re-introducing the new voxel into the relational database.

In one embodiment of the method, the consolidating step comprises a step of selecting some of the attributes and rules for each elementary part as a function of the topology attributes.

In another embodiment, the method further comprises a step of correcting, by the user in the new voxel, all or some of the attributes and rules, tree relationships and topology attributes, prior to the step of re-introducing the new voxel into the relational database.

In one embodiment of the method, the generated knowledge of tree relationships between the elementary parts comprises:
first logical relationships between the elementary position and geometric orientation parts between the elementary parts; and
second logical relationships between the elementary parts based on all or some of the attributes and rules selected by the user.

The present invention also comprises a computer-readable medium comprising instructions which, when they are executed, cause the computer to implement the above method.

The present invention also relates to a system for generating a new technical solution, comprising:
an attributes and rules extractor configured to receive PLM data of an industrial product, and to extract, sort and organize attributes and rules associated with each of the elementary parts forming the industrial product;
a knowledge and relationship graph generator configured to transform and structure a tree breakdown of a PBS of the industrial product forming part of the PLM into a knowledge graph of tree relationships establishing logical relationships between the elementary parts on the geometric and functional levels;
a 3D topology generator and 3D similarities analyzer configured to generate topology attributes associated with each of the elementary parts;
a 3D machine learning system and a voxel and 3D object generator configured to:
consolidate, into one or more relational databases in voxel form per elementary part, the voxel comprising the extracted attributes and rules, the transformed tree relationships, and the generated topology attributes;
receive a request from a user relating to a technical solution, the request comprising at least one 3D volume;
assess whether the technical solution is present in the PLM, and if it is not present:
generate and provide, in response to the request from the user, a new technical solution in the 3D volume, implementing at least one new 3D object;
generate a new voxel associated with the new 3D object; and
re-introduce the new voxel into the relational database.

In one embodiment of the system, the voxel and 3D object generator is further configured to receive a correction, by the user in the new voxel, of all or some of the attributes and rules, tree relationships, and topology attributes, prior to the step of re-introducing the new voxel into the relational database.

In another embodiment of the system, the generated knowledge of tree relationships between the elementary parts comprises:
first logical relationships between the elementary position and geometric orientation parts between the elementary parts; and
second logical relationships between the elementary parts based on all or some of the attributes and rules selected by the user.

Within the scope of this description, unless expressly stated otherwise, a “processor” can refer to, but is not limited to, any type of “computer system”, “electronic device”, “computerized system”, “control unit”, “monitoring device”, “server” and/or any combinations thereof that are suitable for the relevant task, in connection with the reception, storage, processing and/or transmission of data.

Within the scope of this description, the term “FPGA” is intended to include Field Programmable Gate Array type systems available on the market when this patent application was filed, such as the Xilinx VU9P or Intel Stratix V references, and all the equivalent subsequent inventions that become available, irrespective of their name, involving computer system hardware programmable with software.

Within the scope of this description, a “processor” can include a single dedicated processor, a single shared processor, or a plurality of individual processors, some of which can be shared. A “processor” can be a general-purpose processor, such as a central processing unit (CPU), a processor intended for a specific purpose, or a processor implemented in an FPGA. Other conventional and/or custom hardware and software also can be included in a “processor”.

Within the scope of this description, a “computer” equally represents one or more processors capable of reading instructions with a view to executing a function, and/or a function implemented by instructions being executed by one or more processors.

Within the scope of this description, unless expressly stated otherwise, the term “memory” includes random access storage systems available on the market when this patent application was filed, and all the equivalent subsequent inventions that become available, irrespective of their name, involving computer system media for storing digital information. An example of such a memory can be a static random access memory (SRAM).

Within the scope of this description, the functional steps shown in the figures can be performed using dedicated hardware, as well as hardware capable of executing suitable software.

Within the scope of this description, unless expressly stated otherwise, the words “first”, “second”, “third”, etc., have been used as adjectives solely for the purpose of distinguishing the names they accompany from one another, and not for the purpose of describing a particular relationship between these names.

The embodiments of the present invention each have at least one of the aforementioned aims and/or aspects, but do not necessarily have all of them.

Additional and/or alternative features, aspects and advantages of the embodiments of the present invention will become apparent from the following description, the accompanying drawings and the appended claims.

### BRIEF DESCRIPTION OF THE DRAWINGS

In order to better understand the present invention, reference is made to the following description, which should be used in conjunction with the accompanying drawings, in which:

FIG. 1 shows a schematic view of a system in one embodiment of the invention;

FIG. 2 provides a simplified representation of a knowledge graph;

FIG. 3 shows elementary parts of an assembly forming part of an industrial product;

FIG. 4a shows a first part assembly of elementary parts;

FIG. 4b shows a second part assembly of elementary parts, or a design solution;

FIG. 5 provides a simplified representation of the knowledge graph generated in the specific case of elementary parts and part assemblies shown in FIG. 3, FIG. 4a and FIG. 4b;

FIG. 6 provides a schematic representation of the steps of the method according to the invention; and

FIG. 7 illustrates a computer system that can be used to implement the computers shown in FIG. 1, or the method steps of FIG. 6.

It should be noted that, unless explicitly stated otherwise, the drawings are not to scale. Finally, identical elements from one drawing to another use the same reference number.

### DETAILED DESCRIPTION OF THE PREFERRED EMBODIMENTS

The examples and associated conditions described herein are mainly intended to assist the reader in understanding the principles of the present invention and are not intended to limit its scope to these specific examples and conditions. It will be understood that a person skilled in the art can conceive of various arrangements which, although not explicitly described or depicted herein, nevertheless embody the principles of the present invention and are included within its spirit and scope.

Furthermore, for ease of understanding, the following description can describe relatively simplified embodiments of the present invention. As a person skilled in the art will understand, other embodiments of the present invention may be more complex.

In some cases, examples of modifications to the present invention also can be presented. This is simply provided to assist understanding, and again not to define the scope or to establish the limits of the present invention. These modifications are not an exhaustive list, and a person skilled in the art could make other modifications while remaining within the scope of the present invention.

Furthermore, all the following statements relating to the principles, aspects and embodiments of the present invention, as well as the specific examples thereof, are intended to encompass both the structural and functional equivalents thereof, whether they are currently known or are developed in the future. Thus, for example, a person skilled in the art will understand that all the functional diagrams represent conceptual views of examples of circuits incorporating the principles of the present invention. Similarly, it will be clearly understood that all the flowcharts, state transition diagrams, pseudo-codes, and the like represent various processes that can be implemented on computer-readable media and thus can be executed by a computer or a processor, whether or not such a computer or processor is shown in the figures.

The functions of the various elements shown in the figures, including any functional blocks, can be provided by using dedicated hardware, as well as hardware capable of executing suitable software. They also can be executed by a processor. Other conventional and/or customized hardware also can be used.

The software modules, or the modules that are assumed to be software, can be shown herein as a combination of flowchart elements, or of other elements indicating the execution of the steps of a process, and/or as a textual description. Such modules can be executed by hardware that may or may not be expressly shown. Furthermore, it should be understood that a “module” can include, for example, but not be limited to, computer program logic, computer program instructions, software, a software stack, firmware, a hardware circuit, or a combination of these various elements that provides the required capabilities.

With this in mind, some non-limiting examples will now be considered to illustrate various embodiments of the present invention.

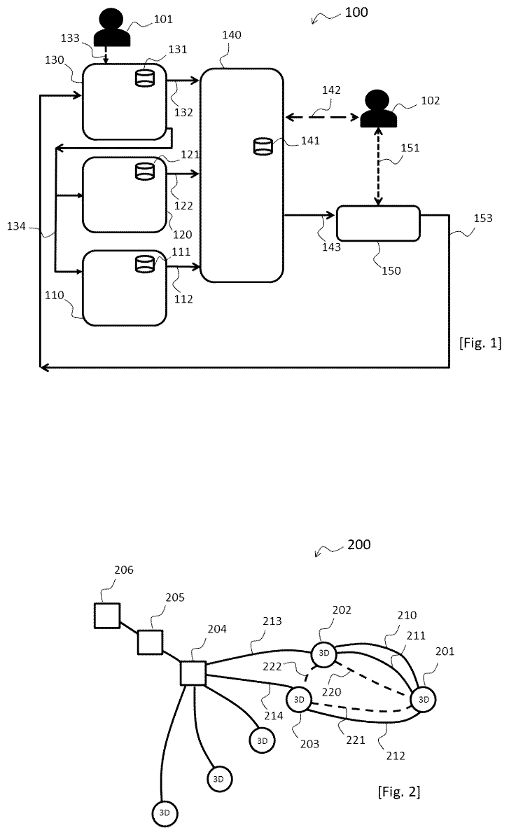

FIG. 1 shows a schematic view of a system 100 in one embodiment of the invention. Data forming a PLM for an industrial product, called PLM data, is provided (133), for example, by an administrator 101. This data allows:
through its use by an attributes and rules extractor 130, the attributes and rules associated with each elementary part forming the industrial product to be sorted and organized;
through its use by a knowledge and relationships graph generator 120, the dependency relationships in a PBS to be used; and
through its use by a 3D topology generator and 3D similarities analyzer 110, the topology attributes of a 3D object to be sorted and organized.

Other means for supplying the system 100 with PLM data, notably during system initialization, can be designed and implemented by a person skilled in the art.

The following are defined within this context:
“Attributes”, such as data associated with an elementary part, designating a specific and distinctive feature of the elementary part, for example: its material, its mass, its designation in a bill of materials, its part number (P/N), its cost, its diameter, its length, etc. ;
“Rules”, such as data associated with an elementary part, relating to the operating methods and processes depending on the trade involved within the context of the industrial product (design, manufacture, maintenance, operation, certification, disposal, recycling, etc.), for example: assembly rules, and, more generally, trade relationships between an elementary part and other elementary parts, etc.;
“Topology attributes”, such as data associated with a 3D object expressing geometric properties that are invariant under geometric deformation, for example: wetted surface area, volume, length, 3D footprint, etc.; and
“tree relationships”, such as organizational and configuration dependency relationships of the industrial product or a part assembly in the PBS. These dependency relationships can be of different types and can be taken individually or in combination, for example:
a parent/child relationship;
a geometric positioning relationship of the elementary parts in relation to each other (for example, face-to-face);
a functional galvanic coupling relationship (for example, comparison of material attributes when the elementary parts are in contact with each other); etc.

The attributes and rules extractor 130 uses, sorts and organizes PLM data relating to attributes and rules associated with an elementary part, and stores it in a set of one or more databases (only one shown: 131). Thus, the database 131 contains at least:
one or more attributes associated with each elementary part; and
one or more rules associated with each elementary part.

The knowledge and relationships graph generator 120 transforms and structures the tree breakdown that forms the PBS of the elementary parts forming the given industrial product into a knowledge graph, which can be depicted as a tree with nodes and structural relationships between the nodes. The generated knowledge graph thus establishes gradual intelligence between the elementary parts, both on a geometric and functional level:
for example, on the geometric level: using relative or absolute position matrices and position orientation matrices, geometric links such as face-to-face (with contact, distance, predefined clearance, etc., where applicable);
for example, on the functional level: by using physical and/or functional trade rules specific to each industrial product, for example, a “fastener” 3D object linked to other 3D objects attached together by this fastener.

The knowledge graph generation function can be implemented using existing software known to a person skilled in the art, for example, the Neo4j Graph Database™ software, but other solutions are available to a person skilled in the art.

The generated knowledge graph can be stored in a set of one or more databases (only one shown: 121).

The 3D topology generator and 3D similarities analyzer 110 generates topology attributes originating from PLM data per 3D object, in order to make it unique by said attributes.

The topology attributes are generated according to criteria selected by the company and adapted to their industrial product, using topological characterization to uniquely characterize each of the elementary parts. The computation is performed on the geometry of the elementary part using numerical values and/or literal designations in order to classify it and link it to its identification number (for example, part number ATA53-unique identification number), which forms part of the attributes.

The 3D topology generator and 3D similarities analyzer 110 thus characterizes all the elementary parts of an industrial product with numerical values and creates a digital fingerprint (one or more unique numerical values) that then can be used to identify them. The topology attributes can be stored in a set of one or more databases (only one shown: 111).

A 3D machine learning system 140 consolidates the following into one or more relational databases (only one database shown: 141) in the form of voxels per elementary part:
topology attributes (111), originating (112) from the 3D topology generator and 3D similarities analyzer 110;
relative positioning information (121) in relation to other elementary parts of the industrial product, originating (122) from the knowledge and relationships graph generator 120; and
attributes and rules for characterizing elementary parts (131), originating (132) from the attributes and rules extractor 130.

A voxel, in a known manner, stores physical information concerning a point in a volume on a regular mesh. It has its own nodal point and orientation coordinates in an accepted coordinate system, its own shape, its own state parameter that indicates its membership of a modelled object, and has properties of the modelled region.

In the present invention, the voxel, as a container, is implemented as conveying a set of data relating to:
an identity and geometric features (the X, Y, Z coordinates, the L, M, N orientation, a direction, etc.);
attributes and other metadata (the attributes, topology attributes, and tree relationships, as defined above); and
associated use rules (the rules, as defined above).

The 3D machine learning system 140 identifies each elementary part originating from the 3D topology generator and 3D similarities analyzer 110, and links it to the knowledge graph generated by the knowledge and relationships graph generator 120, and to the attributes and rules provided by the attributes and rules extractor 130. The data (112, 122, 132) is thus concatenated according to predefined rules (geometry, face-to-face connections, attributes identity, etc., specific to the 3D mode).

The 3D machine learning system 140 thus creates statistical, relational and geometric models of logical interdependencies between the various elementary parts, by characterizing their links in the knowledge graph, enriched with trade, design, computation, manufacturing rules, etc.

The 3D machine learning system 140 also can be capable of discretizing any 3D object into elementary surfaces, 3D sub-objects, in order to be able to manage the 3D objects and create 3D libraries.

The data provided to the 3D machine learning system 140 (112, 122, 132) can be in the form of data tables. This data is used to perform computations of results to be provided to a user 102 (who may be the same person as the administrator 101) communicating (142) with the 3D machine learning system 140, and data to be provided (143) to a voxel and 3D object generator 150.

The 3D machine learning system 140, upon request (142) from the user 102, computes, configures and delivers (142) a technical solution for a part of the industrial product, involving the assembly of one or more elementary parts. The computation and configuration are performed based on the 3D machine learning system 140 learning the attributes, rules, tree relationships and topology attributes. The computation thus takes into account all the available 3D data relating to an industrial product already produced by the company.

This technical solution may already exist (i.e., this technical solution already exists in the PLM), or it even may be new and based on all the criteria of the request by the user 102 (including all or some of: the attributes and rules, tree relationships and topology attributes) in order to propose a new technical solution that is as close as possible to a physically feasible technical solution.

In this latter case (new technical solution), the 3D machine learning system 140 provides a voxel and 3D object generator 150 with the information required for generating the associated 3D objects and voxels describing the new technical solution.

The request (142) from the user 102 includes, for example, a volume in a 3D area of a 3D digital mock-up, or a topological family of 3D objects (for example, all the 3D objects that have a given volume and/or a given wetted surface area) through one or more topology attributes.

The voxel and 3D object generator 150 links topology attributes per 3D object with X, Y, Z coordinates of the centers of gravity of the 3D objects, in order to generate one or more voxels, enriched with attributes and rules.

These 3D objects and associated voxels are then re-introduced (153) into the attributes and rules extractor 130. Before re-introducing them, the user 102 can check (151) the computations made by the voxel and 3D objects generator 150 and, if necessary, manually correct or enrich the 3D objects and associated voxels, and all or some of the proposed attributes and rules, tree relationships, and topology attributes.

In the case of a new technical solution, the voxel and 3D object generator 150 can implement, for example, known Pathfinding Unity™ software. With this function it is thus possible, for example, to redesign a part in a 3D volume from a request from the user 102, including its breakdown into existing or newly generated 3D objects and associated voxels.

FIG. 2 provides a simplified representation of the knowledge graph generated by the knowledge and relationships graph generator 120. This knowledge graph is generated from the industrial product structure known in the PLM and communicated through the link 134. The structure of the industrial product was created during the design activity: each 3D object forming the industrial product was actually designed and positioned in the digital space. The 3D objects have mutual position matrices and orientations, which are defined during the design activity with CAD software, form part of the PLM data, and are stored in PLM tables and databases 131. In addition, a “parent/child” relationship code (product structure tree) is generated, which allows, for each model, its parent(s) and its position in the product structure to be identified.

Three 3D objects 201-203 are shown as an example. The 3D objects are defined by the CAD tools and, by virtue of the 3D topology generator and 3D similarities analyzer 110, are characterized by numerical values characteristic of the topology (topology attributes, as defined above), which allows them to be organized and stored in the database 141 in this numerical format. Each 3D object is thus associated with its part number (part of the attributes), its tree relationships, and its topology attributes, which information is stored in the databases 131, 121, and 111, respectively.

First logical relationships 210-211 and 212 between 3D objects 201/202 and 201/203, respectively, are shown. These logical relationships are linked to the PBS data through the creation of the knowledge graph from the product structure implemented by the knowledge graph generator 120. Through these logical relationships, a geometric position and orientation relationship exists between the 3D objects, which is defined and leveraged in order to link these 3D objects together on a first relational level.

For example, the 3D object 201 represents a fastener, positioned (matrix and orientation relationships) at two geometric positions relative to the 3D object 202 (logical relationships 210-211), and at a single geometric position relative to the 3D object 203 (logical relationship 212).

Other initial logical relationships 213 and 214 between a part assembly 204 of the industrial product and, respectively, the 3D object 202 and the 3D object 203 are shown. These logical relationships are also linked to the PBS data through the creation of the knowledge graph from the product structure implemented by the knowledge graph generator 120. Several 3D objects are thus consolidated into a part assembly 204, then gradually into a part assembly 205, a part assembly 206, and so on until the complete industrial product is obtained. The 3D models are thus organized into groups corresponding to a breakdown of the industrial product into part assemblies, in so doing following the structure of the industrial product.

Second logical relationships 220, 221, 222 between 3D objects 201/202, 201/203 and 202/203, respectively, are shown. These logical relationships are linked to the PLM and PBS data: this is a second relational level between the 3D objects, which, beyond the parent/child relationship, implements the attributes and rules.

For example:
within the context of an assembly of two 3D objects, a “galvanic coupling” constraint rule can exist between the corresponding parts. By constructing the second relational level logical relationship, it is possible to ensure that the “Material” attribute correctly characterizes the 3D object, with this attribute allowing the compatibility of the materials in the galvanic coupling to be checked;
using the above example of a fastener (3D object 201) used to assemble two parts (3D objects 202 and 203): logical relationships 220 and 221 define the type of perforation in each of the two parts that is compatible with the fastener, as a function of attributes (for example, diameter, length, type of fastener, etc.) and according to rules (for example, company-specific design and perforation rules), information stored in the database 131.

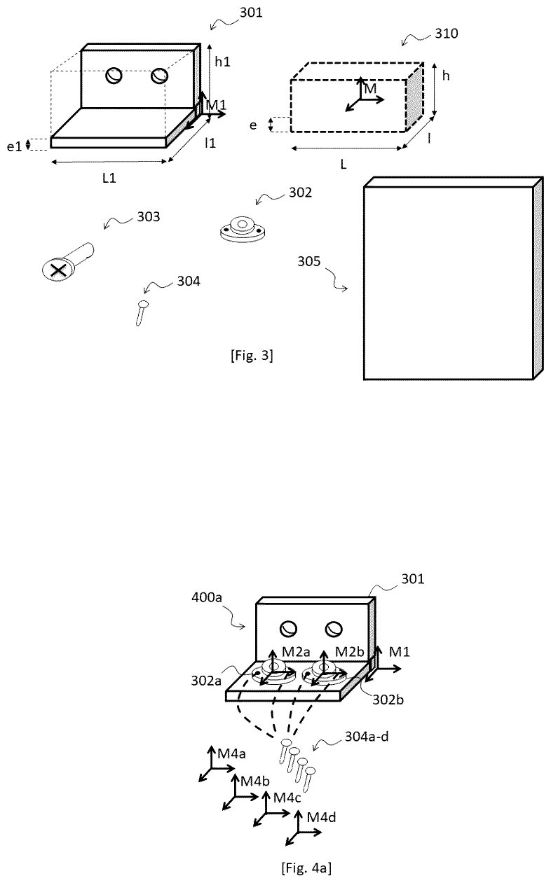

FIGS. 3 to 5 illustrate a simplified embodiment of the invention.

FIG. 3 shows elementary parts of an assembly forming part of an industrial product:
an angle bracket 301 perforated with two holes;
a floating nut 302 perforated with two holes;
a bolt 303;
a rivet 304; and
a structural frame 305.

A generic boundary box (BBOX) is shown under reference 310: such a generic boundary box is intended to characterize, through the digital mock-up, each 3D object for each of the elementary parts 301-303 and 305. Such characterization is carried out, for example, using an orientation matrix M relative to a reference frame (for example, a reference point made up of a matrix M-Ref for the industrial product), the 3D object contained in the boundary box, and Xmin/Xmax, Ymin/Ymax, and Zmin/Zmax parameters, which define the height (h), width (l), and length (L) of the 3D object. Another parameter can be a thickness (e), as in the case of a folded metal sheet forming an angle bracket.

All these parameters are generated in the 3D topology generator and 3D similarities analyzer 110 in FIG. 1.

The generic boundary box 310 applied to the elementary part 301, for example, characterizes the corresponding 3D object through its height h1, width l1, length L1, thickness e1, as well as an orientation matrix M1.

FIG. 4a shows a first part assembly of elementary parts. It implements:
the angle bracket 301;
two floating nuts 302a and 302b; and
four rivets 304a-d.

Some of these elementary parts are 3D objects, others are not. Once each 3D object has been designed and positioned in the digital space, the 3D objects have mutual matrix relationships, which are defined during the design activity with CAD software, form part of the PLM data, and are stored in PLM tables and databases 131. The rivets 304a-d represent an example of elementary parts that are not 3D objects. They form part of the PLM data as elementary parts, for example, within a bill of materials (BOM), but are not present in a digital mock-up. They form part of the PLM data, with their associated attributes, rules and topology attributes. In particular, they thus have an associated orientation matrix.

Thus:

M1 is the orientation matrix of the angle bracket 301;

M2a (respectively: M2b) is the orientation matrix of the floating nut 302a (respectively: 302b); and

M4a-d are the orientation matrices of the rivets 304a-d, respectively.

The first part assembly is formed by:
perforating the angle bracket 301 at four locations according to the spacing of four holes on the floating nuts 302a and 302b; and
positioning the floating nuts 302a and 302b, and assembling them on the angle bracket 301 using the four rivets 304a-d.

FIG. 4b shows a second part assembly of elementary parts, or design solution. In addition to the first part assembly, it implements:
two bolts 303a and 303b; and
the structural frame 305. M3a (respectively: M3b) is the orientation matrix of the floating nut 303a (respectively: 303b).

M5 is the orientation matrix of the structural frame 305.

The second part assembly or design solution is formed by:
perforating the structural frame 305 at two locations according to the spacing of two holes on the angle bracket 301; and
positioning the angle bracket 301 and assembling it on the structural frame 305 using the two bolts 303a and 303b.

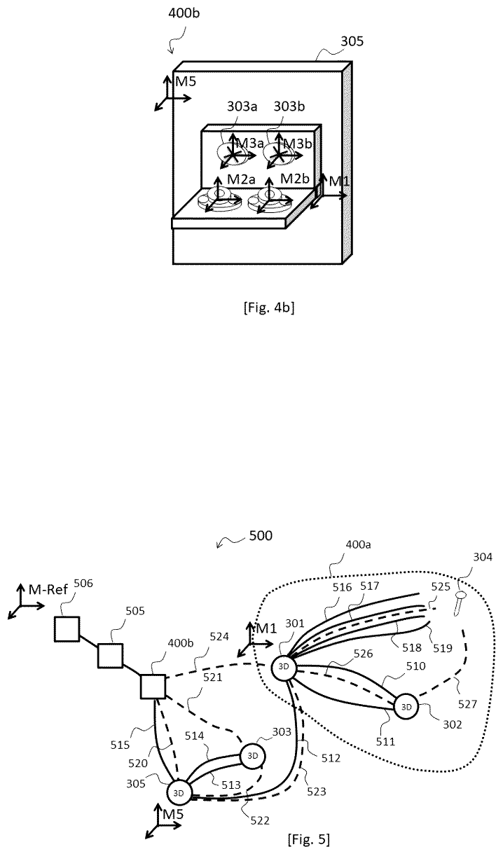

FIG. 5 provides a simplified representation of the knowledge graph generated by the knowledge and relationships graph generator 120, in the specific case of the elementary parts and part assemblies shown in FIG. 3, FIG. 4a and FIG. 4b.

All the 3D objects 301-303 and 305 are defined by CAD tools and, by virtue of the 3D Topology generator and 3D similarities analyzer 110, are characterized by numerical values characteristic of the topology (topology attributes, as defined above), which allows them to be organized and stored in the database 141 in this digital format. Each 3D object is thus associated with its part number (part of the attributes), its tree relationships, and its topology attributes, which information is stored in the databases 131, 121 and 111, respectively.

The rivets 304a-d are not shown as 3D objects but as elementary parts that are not 3D objects.

Initial logical relationships are established:
516-519, between each of the four instances of the rivet 304, corresponding to the four rivets 304a-d in FIG. 4a, and the angle bracket 301;
510-511, respectively between two instances of the floating nut 302, corresponding to the two floating nuts 302a-b in FIG. 4a, and the angle bracket 301;
512, between the angle bracket 301 and the structural frame 305;
513-514, respectively between two instances of the bolt 303, corresponding to the two bolts 303a-b in FIG. 4b, and the structural frame 305; and
515, between the structural frame 305 and the part assembly or design solution 400b.

All these initial logical relationships 51x are linked to the PBS data through the creation of the knowledge graph from the product structure implemented by the knowledge graph generator 120. Through these logical relationships, a geometric position and orientation relationship exists between the elementary parts, which is defined and leveraged to link them together on a first relational level.

Thus, notably, through these logical relationships 51x, the relationships between orientation matrices are established:
for the part assembly 400a: M2a-b/M1 and M4a-d/M1; and—for the part assembly or design solution 400b: M1/M5, and M3a-b/M5.

Second logical relationships are established:
520, 521, 524 respectively between the 3D objects of the structural frame 305, the bolt 303, and the angle bracket 301, and the part assembly or drawing solution 400b;
522, between the 3D object of the structural frame 305 and the bolt 303;
523, between the 3D object of the structural frame 305 and the angle bracket 301;
525, 527 between the rivet 304 and, respectively, the angle bracket 301 and the floating nut 302, respectively; and
526, between the floating nut 302 and the angle bracket 301.

All these second logical relationships 52x are linked to the PLM and PBS data: this is a second relational level between the elementary parts, which, beyond the parent/child relationship, implements the attributes and rules.

Several elementary parts are thus consolidated into part assemblies 400a and 400b, as shown in FIG. 4a and FIG. 4b, then gradually into a part assembly 505, a part assembly 506, and so on until the complete industrial product is obtained. The elementary parts are thus organized into groups corresponding to a breakdown of the industrial product into part assemblies, in so doing following the structure of the industrial product. Through other logical relationships (not numbered) between the part assembly or design solution 400b, the part assembly 505, and the part assembly 506, the relationships between orientation matrices are established:
M5/M-Ref.

Thus, in the example in FIG. 5:
the logical relationship 522 can include a linking rule between each instance of the bolt 303 and the structural frame 305, comprising, for example, the perforation diameter of the two holes in the structural frame 305, or the required tightening force between the two;
the logical relationship 523 can include a linking rule between the angle bracket 301 and the structural frame 305, for example, the sides of each that must face each other;
the logical relationship 525 can include attributes, for example, lists of references to standard market elements of the type of rivet 304.

Each company can select which attributes and rules it wishes to link for the correct management of its industrial product.

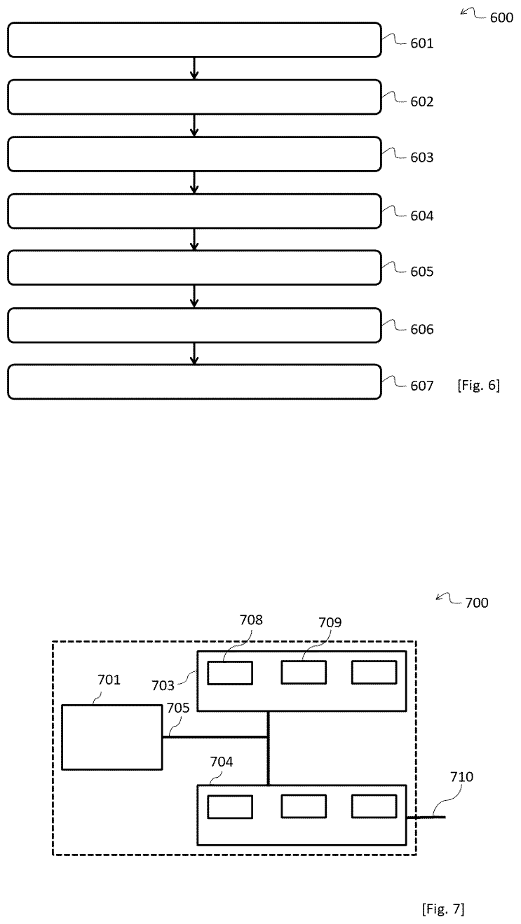

FIG. 6 provides a schematic representation of the steps of the method 600 implemented, for example, by a computer according to the invention.

In step 601, the method involves acquiring PLM data of an industrial product comprising at least two elementary parts, at least one of which is a 3D object generated by a 3D digital mock-up.

In step 602, the method involves extracting PLM data from the attributes and rules for each elementary part.

In step 603, the method involves generating a knowledge graph of tree relationships establishing logical relationships between the elementary parts on the geometric and functional levels.

In step 604, the method involves generating topology attributes for each elementary part.

In step 605, the method involves consolidating, for each elementary part, its attributes and rules, its tree relationships and its topology attributes into at least one relational database, in voxel form.

In step 606, the method involves receiving a request from a user (102) relating to a technical solution, with the request comprising at least one 3D volume. In step 607, the method involves evaluating whether the technical solution is present in the PLM, and if it is not present: generating and providing, in response to the request from the user (102), a new technical solution in the 3D volume, implementing at least one new 3D object, generating a new voxel associated with the new 3D object; and re-introducing the new voxel into the relational database.

FIG. 7 illustrates a computer system that can be used, for example, to implement the one or more computers used in the attributes and rules extractor 130, the knowledge and relationships graph generator 120, the 3D topology generator and 3D similarities analyzer 110, the 3D machine learning system 140, and/or the voxel and 3D object generator 150, and/or the method steps according to FIG. 6. As will be understood by a person skilled in the art, such a computer system can be implemented in any other suitable hardware, software and/or firmware, or a combination thereof, and can be a single physical entity or a plurality of separate physical entities with distributed functionality.

The computer system 700 can comprise various hardware components, including one or more single-core or multi-core processors collectively represented by a processor 701, a memory 703, and an input/output interface 704. Within this context, the processor 701 may or may not be included in an FPGA. The computer system 700 can be a generic “ready to use” computer system. The computer system 700 also can be distributed across multiple systems. The computer system 700 also can be specifically dedicated to implementing the present invention. As a person skilled in the art of the present invention will understand, multiple variations of how the computer system 700 is implemented can be contemplated.

Communication between the various components of the computer system 700 can be enabled by one or more internal and/or external buses 705 (for example, a PCI bus, a universal serial bus, an IEEE 1394 “Firewire” bus, an SCSI bus, a Serial-ATA bus, an ARINC bus, etc.), to which the various hardware components are electronically coupled.

The input/output interface 704 can enable networking capabilities such as wired or wireless access. By way of an example, the input/output interface 704 can include a network interface such as, but not limited to, a network port, a network socket, a network interface controller, and the like. Multiple examples of how the networking interface can be implemented will become apparent to a person skilled in the art of the present invention.

The memory 703 can store code instructions 708, such as those forming part of, for example, a library, an application, etc., which can be loaded into the memory 703 and executed by the processor 701 in order to, for example, implement the steps of the method according to the present invention. The memory 703 can also store a database 709. A person skilled in the art will understand that the database 709, the code instructions 708 and generally the memory 703 can also physically reside outside the computer system 700, still within the scope of the present invention.

The input/output interface 704 can allow the computer system 700 to communicate with other processors via a connection 710. This can be the case, for example, if the above calibration step is implemented in the computer system 700, while the above correlation step is implemented in a processor outside the computer system 700, for example, on the aircraft.

Although the embodiments described above have been described and depicted with reference to particular steps performed in a particular order, it will be understood that these steps can be combined, subdivided or reordered without departing from the teaching of the present disclosure. At least some of the steps can be executed in parallel or in series. Consequently, the order and the consolidation of the steps do not constitute a limitation of the present invention.

Modifications and improvements to the embodiments of the present invention described above may become apparent to a person skilled in the art. The above description is illustrative by way of examples rather than limiting. The scope of the present invention is therefore only limited by the scope of the following claims.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A method for generating a technical solution involving assembling elementary parts, comprising the steps of:
acquiring PLM data of an industrial product comprising at least two elementary parts, at least one of which is a 3D object generated by a 3D digital mock-up;
extracting attributes and rules for each of the at least two elementary parts from the PLM data;
generating a knowledge graph of tree relationships based on the PLM data and establishing logical relationships between the at least two elementary parts on a geometric level and a functional level;
generating topology attributes based on the PLM data for each of the at least two elementary parts;
consolidating, with a 3D machine learning system for each of the at least two elementary parts, the attributes and rules, the tree relationships and the topology attributes into at least one relational database, in voxel form;
receiving, via the 3D machine learning system, a request from a user relating to the technical solution, the request comprising at least one 3D volume and a topology attribute characterizing the at least two elementary parts assembled in the technical solution;
evaluating, via the 3D machine learning system, whether the technical solution is present in the PLM, and when it is not present:
generating and providing, in response to the request from the user, a new technical solution in the 3D volume, implementing at least one new 3D object;
generating a new voxel associated with the new 3D object; and
re-introducing the new voxel into the at least one relational database.

2. The method according to claim 1, wherein the consolidating step comprises a step of selecting some of the attributes and rules for each of the at least two elementary parts as a function of the topology attributes.

3. The method according to claim 1, further comprising a step of:
correcting, by the user in the new voxel, all or some of the attributes and rules, tree relationships and topology attributes, prior to the step of re-introducing the new voxel into the at least one relational database.

4. The method according to claim 1, wherein the knowledge graph of tree relationships between the elementary parts comprises:
first logical relationships between an elementary position and a geometric orientation parts between the at least two elementary parts; and
second logical relationships between the at least two elementary parts based on all or some of the attributes and rules selected by the user.

5. A non-transitory computer-readable medium comprising instructions which, when executed by a processor of a computer, cause the computer to implement the method of claim 1.

6. A system for generating a technical solution involving assembling elementary parts, comprising:
an attributes and rules extractor configured to receive PLM data of an industrial product comprising at least two elementary parts, and to extract, sort and organize attributes and rules associated with each of the at least two elementary parts forming the industrial product;
a knowledge and relationships graph generator configured to transform and structure a tree breakdown of a PBS of the industrial product forming part of the PLM into a knowledge graph of tree relationships based on the PLM data and establishing logical relationships between the at least two elementary parts on a geometric level and a functional level;
a 3D topology generator and 3D similarities analyzer configured to generate topology attributes based on the PLM data and associated with each of the at least two elementary parts;
a 3D machine learning system and a voxel and 3D object generator configured to:
consolidate, into one or more relational databases in voxel form per elementary part, the voxel comprising the extracted attributes and rules, the tree relationships, and the topology attributes;
receive a request from a user relating to a technical solution, the request comprising at least one 3D volume and a topology attribute characterizing the at least two elementary parts assembled in the technical solution;
assess whether the technical solution is present in the PLM, and when it is not present:
generate and provide, in response to the request from the user, a new technical solution in the 3D volume, implementing at least one new 3D object;
generate a new voxel associated with the new 3D object; and
re-introduce the new voxel into the one or more relational databases.

7. The system according to claim 6, wherein the voxel and 3D object generator is further configured to receive a correction, by the user in the new voxel, of all or some of the attributes and rules, tree relationships, and topology attributes, prior to the step of re-introducing the new voxel into the one or more relational databases.

8. The system according to claim 6, wherein the knowledge graph of tree relationships between the elementary parts comprises:
first logical relationships between an elementary position and a geometric orientation parts between the at least two elementary parts; and
second logical relationships between the at least two elementary parts based on all or some of the attributes and rules selected by the user.
